(19) United States
(12) Patent Application Publication
(10) Pub. No.: US 2008/0024039 A1
(43) Pub. Date: Jan. 31, 2008

(54) Micro-actuator, HGA equipped with the micro-actuator and method for manufacturing the HGA

(75) Inventor: Minggao Yao, Hong Kong (CN)

Correspondence Address: COURTNEY STANIFORD & GREGORY LLP, P.O. BOX 9686, SAN JOSE, CA, 95157, US

(73) Assignee: SAE Magnetics (H.K.) Ltd.

(21) Appl. No.: 11/492,548

(22) Filed: Jul. 25, 2006

(51) Int. Cl. H01L 41/00

(52) U.S. Cl. 310/328; 310/330

(57) ABSTRACT

A micro-actuator used in HGA of the disk drive unit is provided. The micro-actuator comprises a metal frame which includes a base piece and two opposite arms extending from the base piece, in which at least two pieces of thin film PZT are attached to the side surface(s) of each one of said two opposite arms respectively in such a manner that the displacement of each arm is increased due to the superposition effect when each arm displaces together with the thin film PZT attached thereon in response to drive signal(s) applied to the thin film PZT. Since at least two pieces of thin film PZT are attached on the side surface(s) of each arm, an increased displacement of the arms can be achieved due to the superposition effect.

### FIELD OF THE INVENTION

The present invention relates to an information recording device, and particularly to a micro-actuator for a head gimbal assembly (HGA) in a disk drive unit and a method for manufacturing the head gimbal assembly equipped with the micro-actuator.

### BACKGROUND OF THE INVENTION

Nowadays, different methods are utilized to improve the recording density of information recording device. FIG. 1 shows a disk drive as an example of information recording device according to the conventional design, in which a spindle motor 15 spins the disk 14, a drive arm 12 controls the head element (not shown) located on the head gimbal assembly (HGA) 18 to fly on the surface of the disk 14. Generally, voice-coil motors (VCM) 16 are used for controlling the motion of drive arm 12 which is configured for course adjustment across the disk 14. Referring to FIG. 2, which is an illustration of a head gimble assembly (HGA) 18 in FIG. 1 equipped with the conventional PZT micro-actuator 181, because there is an inherent tolerance (dynamic play) existing in the displacement of the head element in case of the head element is driven by VCM 16 alone. The micro-actuator 181 provided on the suspension tongue 1831 of suspension 183 of the HGA 18 is for fine position controlling of the head element. The micro-actuator 181 arranged around the head element is usually a piezoelectric Lead Zirconate Titanate (PZT) micro-actuator which now is utilized to ‘fine tune’ the displacement of head element. That is to say, The VCM 16 is utilized for course adjustment and the PZT micro-actuator 181 then adjusts the displacement of the head element in a much smaller scale to compensate for the vibration of the drive arm 12 caused by the driving of VCM 16. The HGA 18 with above structure allows for a much smaller recordable track width, whereby the ‘tracks per inch’ (TPI) value of the disk drive is increased by up to 50%.

More specifically, in conventional design of HGA 18 shown in FIG. 2a, a slider 182 on which the head element (not shown) is attached is utilized for maintaining a prescribed flying height above the surface of disk 14 (See FIG. 1). FIG. 2b further shows the structure of the conventional micro-actuator 181, in which U shape micro-actuator 181 includes a ceramic frame having two ceramic arms 1811 between which a slider 182 is to be arranged, and two pieces of ceramic PZT 1813 attached to the outer surfaces of each ceramic arm 1811. Referring back to FIG. 2a, The PZT micro-actuator 181 is physical attached to the suspension tongue 1831 of the suspension 183 of the HGA 18 in a manner that the slider 182 can move independently of the suspension 183 in response to the voltage applied to the ceramic PZT 1813. More specifically, There are three electric connection balls 185 (GBB or SBB—gold ball bonding or solder bump bonding) attaching the micro-actuator 181 to the suspension traces 184 in each side of the ceramic arms 1811, and similarly, there are four balls 186 (GBB or SBB) attaching the slider 182 to the suspension traces 184 of which the other ends are connected to the suspension pad 187 so that the voltage source may be input through the suspension trace 184. The PZT will expand and contract, which will cause deformation of the ceramic arms 1811 of the U shape micro-actuator 181 and accordingly cause the slider 182 to move on the disk, this is going to do the position fine adjustment of the head element attached on the slider 182.

Since the conventional design of HGA employs a U shape ceramic micro-actuator, also the PZT element is made of ceramic material; the undesired big mass of the ceramic material may affect the HGA dynamic performance. In addition, since the ceramic material is a fragile material, the shock performance of the ceramic micro-actuator is limited and the undesired particles may be generated during the work procedure.

In order to reduce the weight of the micro-actuator and improve the dynamic performance of the HGA, U.S. Pat. No. 6,950,288 by Yao et al disclosed a micro-actuator using a metal frame. More specifically, the frame is made from stainless steel. By using a metal frame the dynamic performance of the micro-actuator is improved greatly.

On the other hand, a thin film PZT is proposed for addressing the shock performance and particle generation issue in recent years. However, the thin film PZT cannot generate sufficient displacement due to its limited layer number. Although the displacement of the thin-film PZT can be increased by forming the thin-film PZT to be multi-layered, due to the limitation of the forming process of the thin-film PZT, the cost will become extremely high if the layer number of the thin-film PZT is in excess of 2.

Therefore, there is a need of increasing the displacement of the micro-actuator employing the thin film PZT in a cost-effective way.

### SUMMARY OF THE INVENTION

In view of the disadvantages of prior art, the primary object of this invention is to provide a micro-actuator used in the HGA of the disk drive unit, which allows for a perfect dynamic performance and shock performance of the HGA, meanwhile can produce increased displacement in a cost-effective way.

To achieve above object of this invention, this invention provides a micro-actuator comprising a metal frame which includes a base piece and two opposite arms extending from the base piece, in which at least two pieces of thin film PZT are attached to the side surface(s) of each one of said two opposite arms respectively in such a manner that there is a superposition effect on the displacement of each arm when each arm displaces together with the thin film PZT attached thereon in response to drive signal(s) applied to the thin film PZT.

Specifically, this invention provides a micro-actuator formed by attaching thin film piezoelectric Lead Zirconate Titanate (PZT) to the side surfaces of each arm of the metal frame, which can reduce the total mass of the HGA, and improve the HGA static and dynamic performance. On the other hand, by attaching at least two pieces of thin-film PZT to the side surface(s) of each arm of the metal frame, a superposition effect on the displacements of the arm, i.e., on the displacement of the head element occurs, thereby an increased displacement of the head element can be achieved.

In addition, the thin film PZT has a much smaller mass than the ceramic PZT, which will contribute a lot to the HGA performance and the HGA manufacturing process, for example, the shock performance is better since the mass is reduced. On the other hand, the manufacture tolerance is also reduced due to the accuracy dimension control of the thin film PZT.

In addition to above advantages, the thin film PZT can be operated with lower voltage and thus fewer particles are generated and less power is consumed during operation, and high shock performance and very safe operation condition can be obtained.

Preferably, two pieces of thin film PZT are attached to the exterior and inner side surfaces of each said arm respectively. With this double mounted structure, the displacement of the micro-actuator will be greatly increased since the equivalent working layer number of the thin film PZT attached to each arm is doubled without actually increasing the layer number of each piece of thin film PZT. Thereby the displacement can be increased in a cost-effective way.

Preferably, the two pieces of thin film PZT attached to the exterior and inner side surfaces of each arm are coupled together mechanically and electrically by a substrate, this facilitates the attaching and positioning of the thin film PZT to the side surfaces of the arms.

Preferably, said two pieces of thin film PZT are coupled by the substrate in such manner that the substrate crosses over the front or rear end of the arm.

Preferably, the two pieces of thin film PZT are coupled by the substrate in such manner that the substrate crosses over the top edge of the arm.

Preferably, said substrate is of soft polymer, on which electrical traces are formed for electrically coupling the two pieces of thin film PZT together.

These two pieces of thin film PZT can be attached to each arm of the metal frame in other way. More specifically, the two pieces of thin film PZT can be attached to the same side surface of each said arm. That is to say, both the two pieces of the thin-film PZT can be attached to the exterior or the inner surface of each arm in series. In this case the superposition effect is also available. However, to achieve maximum displacement, the length of each pieces of the thin film PZT should be about 1 mm.

Preferably, a support is formed on the other end of each arm opposite to the base piece for holding a slider, said support being located in different parallel plane from the base piece so that a gap exists between the bottom of the support and that of the base piece.

On the other aspect of this invention, a head gimbal assembly is provided, which comprises a micro-actuator as above-described; a slider with at least one head element, said slider being accommodated in said metal frame so that said slider can be actuated by said micro-actuator; and a suspension, said micro-actuator being located on the suspension tongue of said suspension by fixing the base piece thereto such that said two arms together with the slider can move independently of the suspension.

On the further aspect of this invention, an information recording disk unit is provided, which comprises a disk; a pivot center, about which said disk rotates, a VCM for driving a head element to move above the surface of the disk, and a head gimbal assembly connected to said VCM for head displacement adjustment, wherein said head gimbal assembly comprises a micro-actuator as described above.

A method of manufacturing a head gimbal assembly is also provided, which comprises the steps of: attaching two pieces of thin film PZT to the inner and exterior side surfaces of each arms of a metal frame respectively to form a micro-actuator; mounting a slider with a head element within the micro-actuator; mounting the micro-actuator on a suspension by fixing a base piece of the metal frame onto a suspension tongue of the suspension; connecting the micro-actuator with the suspension and the head slider with the suspension electrically.

Preferably, said step of attaching thin film PZT to the side surface of each arm further comprises following steps: providing two strips of thin film PZT, each strip of the thin film PZT is constituted by two pieces of thin film PZT coupled by a substrate mechanically and electrically, bending each strip of thin film PZT at the middle portion of the substrate such that two pieces of thin film PZT constituting each strip of thin film PZT are substantially parallel to each other, attaching the folded two pieces of thin film PZT to the exterior and inner surface of each of the arms respectively in a manner that said each of the arms are sandwiched by the folded two pieces of the thin film PZT and said substrate crosses over the arm.

Accordingly, another method for manufacturing a head gimbal assembly comprises the steps of: attaching two pieces of thin film PZT to same side surface of each arms of a metal frame in series to form a micro-actuator; mounting a slider with a head element within the micro-actuator; mounting the micro-actuator on a suspension by fixing a base piece of the metal frame onto a suspension tongue of the suspension; connecting the micro-actuator with the suspension and the head slider with the suspension electrically.

Other characteristics and advantages of this invention will become apparent on reading following detailed description of the embodiments of the invention, given as examples only, and with reference to the drawing.

### BRIEF DESCRIPTION OF THE DRAWINGS

FIG. 1 provides an illustration of a typical disk drive unit using the conventional micro-actuator for head position control.

FIG. 2a is a detail view of the HGA configuration of FIG. 1;

FIG. 2b is a detail view of the conventional micro-actuator;

FIGS. 3a˜3f show a micro-actuator and its components according to first embodiment of this invention and the variant thereof;

FIGS. 4a˜4c show a micro-actuator and its components according to second embodiment of this invention.

FIG. 5 shows a simulation data of the displacement of the PZT with respect to the PZT length and the layer number;

FIGS. 6a˜6b show a micro-actuator and its components according to third embodiment of this invention.

FIG. 7a is a structural view of HGA equipped with the micro-actuator according to this invention;

FIG. 7b is a perspective detailed view of the front portion of the suspension of the HGA shown in FIG. 7a;

FIG. 7c is a side view of the front portion of the suspension of the HGA shown in FIG. 7a, in which a micro-actuator according to this invention is equipped;

FIG. 8 is a flow chart showing a process of manufacturing the HGA according to this invention; and

FIG. 9 shows a disk drive unit using the micro-actuator of this invention.

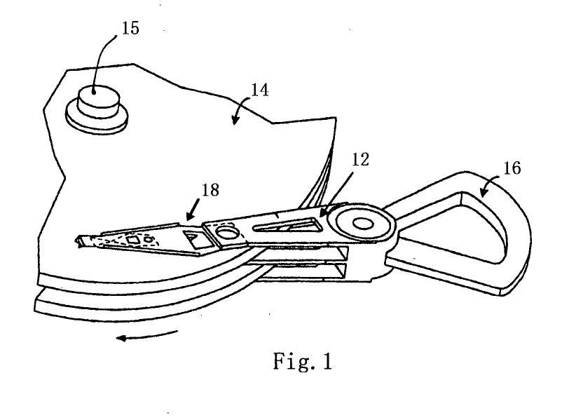

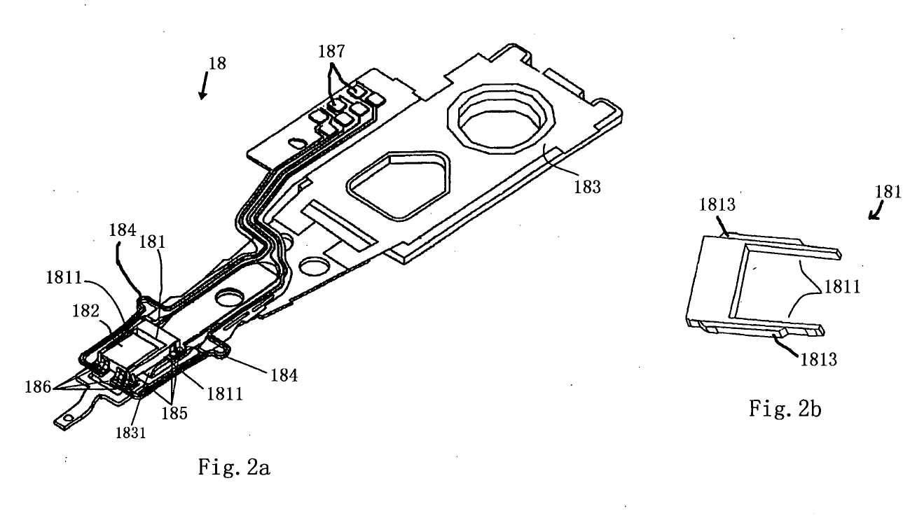

### DESCRIPTION OF THE PREFERRED EMBODIMENTS

This invention relates to the micro-actuator, the HGA using this micro-actuator and the disk drive unit comprising the HGA.

Same or similar reference numerals are used for same or similar components throughout the description.

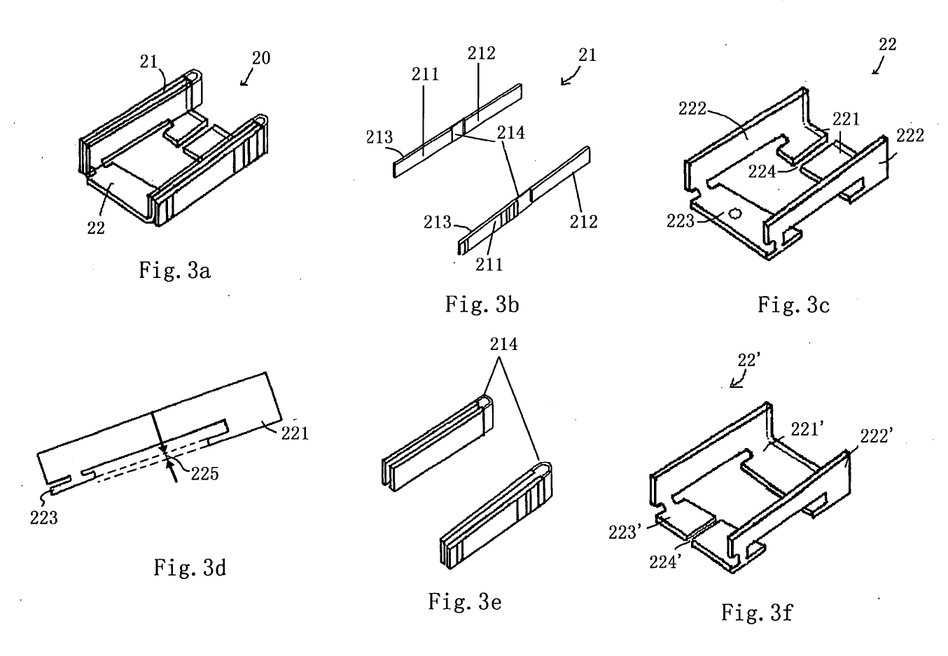

FIGS. 3a-3e are detail structural views of the micro-actuator and its components according to the first embodiment of this invention.

FIG. 3a is a structural view of assembled micro-actuator 20 according to the first embodiment of this invention. The micro-actuator 20 includes thin film PZT 21 and metal frame 22 on which the thin film PZT 21 attached. Following are the detailed description to the structure of thin film PZT 21 and metal frame 22 and the assembling process thereof.

FIG. 3b shows the thin film PZT 21 used in the micro-actuator 20. The thin film PZT 21 is constituted by a first thin film PZT piece 211 and a second thin film PZT piece 212 which are coupled by a substrate 213 such as a soft polymer in such a manner that the first and second PZT piece 211 and 212 are arranged on the substrate 213 in longitudinal direction (in series) and spaced apart from each other by a certain distance. In other words, the substrate 213 is a common substrate of the two pieces thin film PZT 211 and 212, and the end edges of the two pieces thin film PZT are opposite to each other. Electric traces (not shown) are formed on the substrate 213 for coupling the two pieces of thin film PZT 211 and 212 electrically.

FIG. 3c shows a structure of the metal frame 22 according to the first embodiment of this invention. The metal frame 22, which is made preferably from stainless steel, includes a base piece 221 and two arms 222 extending from said base piece 221. A support 223 is formed at the other end of arms 222 opposite to the base piece 221. In other words, two arms 222 are substantially vertical to and extend from the base piece 221 and support 223 at each end. In this embodiment, the metal frame 22 is formed of a single metal plate after double forming process, and there is a gap 224 formed in the base piece 221.

FIG. 3d is a side view of this metal frame 22. As can been seen, the base piece 221 is formed on different plane from the support 223, there is a step difference 225 formed in vertical direction between the base piece 221 and support 223, which facilitates the front portion of the frame 22 to move smoothly when mounting the base piece 221 to the suspension tongue of the suspension of the HGA, as will be further described in future.

FIG. 3e shows a structural state of the thin film PZT 21 after being bended at the middle portion 214 of polymer soft substrate 213 such that the first and second thin film PZT pieces 211 and 212 are substantially parallel to each other, and a inner spacer is existed which will fit for mounting the pieces of thin film PZT to inner and exterior surfaces of the arms 222 of the metal frame 22.

By mounting the bended thin film PZT 21 to the metal frame 22 such that the two pieces of thin film PZT 211 and 212 are attached to the inner and exterior side surfaces of the arm 222 respectively with the middle portion 214 crossing over the rear (or front) end of the arm 222, that is to say, by sandwiching the arms 222 between two thin-film PZT pieces 211 and 212, the micro-actuator 20 shown in FIG. 3a of first embodiment is formed.

With this double mounted structure, the displacement of the micro-actuator will be greatly increased since the equivalent working layer number of the thin film PZT attached to each arm is actually doubled without indeed increasing the layer number of each piece of thin film PZT. Thus the result displacement of the micro-actuator is a superposition of the displacements of two pieces of thin film PZT attached to each arm of the metal frame. More specifically, with a two-layer thin film PZT attached to the arm by such double mounted manner, the equivalent layer number of the thin film PZT on each arm is four, thus the displacement of the micro-actuator will be increased by twice, thereby the displacement is increased in a cost-effective way.

FIG. 3f shows another instance of the metal frame 22′ which can be employed in this embodiment, in which the gap 224′ is formed in the support 223′ of the metal frame 22′, instead of in the base piece 221′.

This embodiment of the invention provides a micro-actuator formed by attaching two pieces of thin film piezoelectric Lead Zirconate Titanate (PZT) to the metal frame structure, which can reduce the total mass of the HGA, and improve the HGA static and dynamic performance, also sufficient displacement of the head element can be achieved by attaching the thin-film PZT pieces both to the inner and exterior side surfaces of each arm of the metal frame.

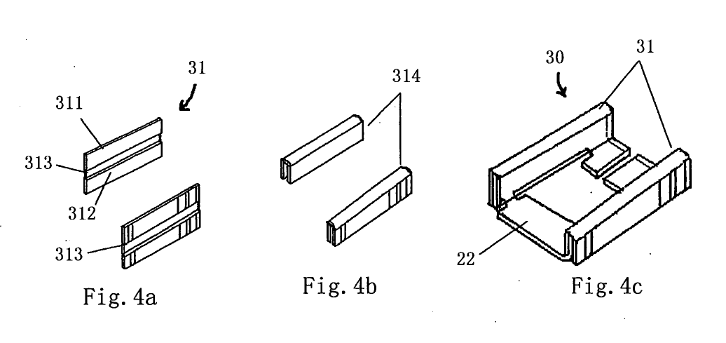

FIGS. 4a to 4c show the second embodiment of the micro-actuator according to this invention. More specifically, FIG. 4a shows two strips of thin film PZT 31 used in the second embodiment of the micro-actuator. Each strip is constituted by the first thin film PZT piece 311 and the second thin film PZT piece 312 which are also coupled together by a substrate 313 in such manner that the first and second PZT piece 311 and 312 are arranged on the substrate 313 in lateral direction (in parallel) and also spaced apart from each other by a certain distance. The second embodiment is different from the first embodiment in that the common substrate 313 joins the two pieces of the thin film PZT such that the side edges of the two thin film PZT pieces are opposite to each other, rather than the end edges. Also electrical traces (not shown) may be formed on the substrate 313 for coupling the two pieces of thin film PZT 311 and 312 electrically.

The metal frame 22 of this second embodiment of the micro-actuator 30 is identical to that of the first embodiment, then further description to the metal frame is omitted. Similarly, another kind of metal frame 22′ can also be employed in the second embodiment.

FIG. 4b shows a structural state of the two strips of thin film PZT 31 after bending the two PZT pieces 311 and 312 at the middle portion 314 of the substrate 313. For the bending purpose, the substrate 313 is preferably a kind of soft polymer. In this bended state, the first and second thin film PZT pieces 311 and 312 are substantially parallel to each other, and a inner spacer is existed which will fit for mounting the pieces of thin film PZT to inner and exterior surfaces of the arms of the metal frame 22.

FIG. 4 c is a structure view of the micro-actuator 30 according to the second embodiment assembled from above-described two strip of thin film PZT 31 and metal frame 22. It is formed by mounting the bended thin film PZT 31 to the metal frame 22 such that two pieces of thin film PZT 311 and 312 are attached to the inner and exterior side surfaces of each arm 222 respectively, with the middle portions 314 crossing over the upper edges of the arms 222. That is to say, each arm of the metal frame 22 is sandwiched between two thin-film PZT pieces 311 and 312.

Similarly, the micro-actuator 30 of the second embodiment also has increased equivalent layer number of the thin film PZT, and thus can produce superposition effect on the displacement of the arm as well.

It is obvious to the ordinary one skilled in this field that the two pieces of thin film PZT attached to the inner and exterior side surfaces of each arm of the metal frame can also be separated to each other completely and are not joined by a substrate, although these two pieces of thin film PZT are joined by a substrate both in the first and second embodiments of this invention. In this case, the first thin film PZT piece and second thin film PZT piece may be electrically connected to the suspension pad via respective suspension traces.

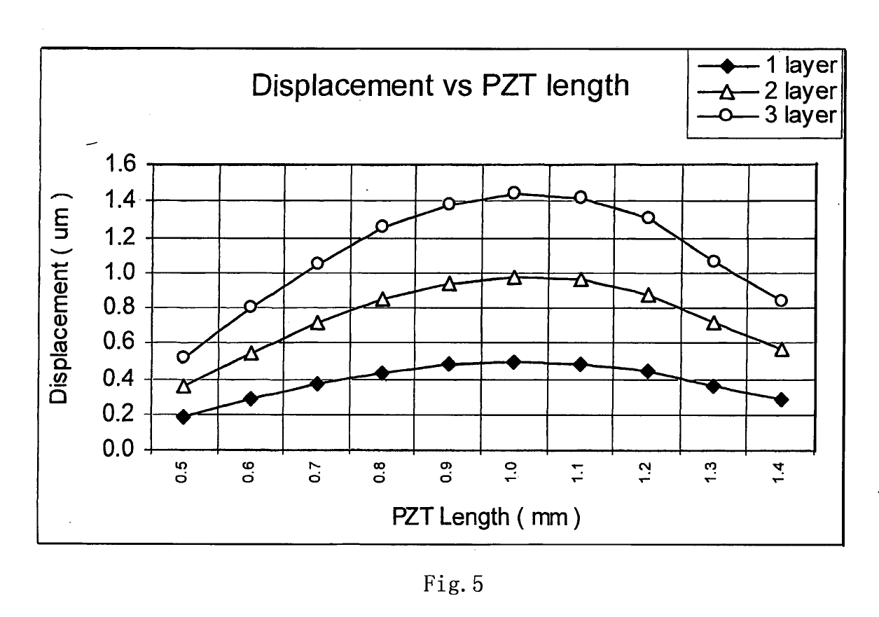

FIG. 5 shows a simulation data of the displacement of the thin-film PZT with respect to the length of the PZT and the layer number of PZT. As can be seen, the displacement of the PZT will increase as the layer number of the PZT increases. Therefore, the first and second embodiments of this invention can effectively increase the displacement of the PZT by increasing the equivalent layer number of the thin film PZT attached to each arm.

On the other hand, we can also learn from FIG. 5 that the displacement of the PZT will increase as the length of the PZT increases firstly, however it will decrease as the length of the PZT further increases. The maximum displacement of the PZT occurs at the certain length point of PZT (this certain length point is about 1 mm, according to FIG. 5). Based on this character of the PZT, we can also increase the displacement of the PZT by choosing appropriate length of each piece of the thin film PZT.

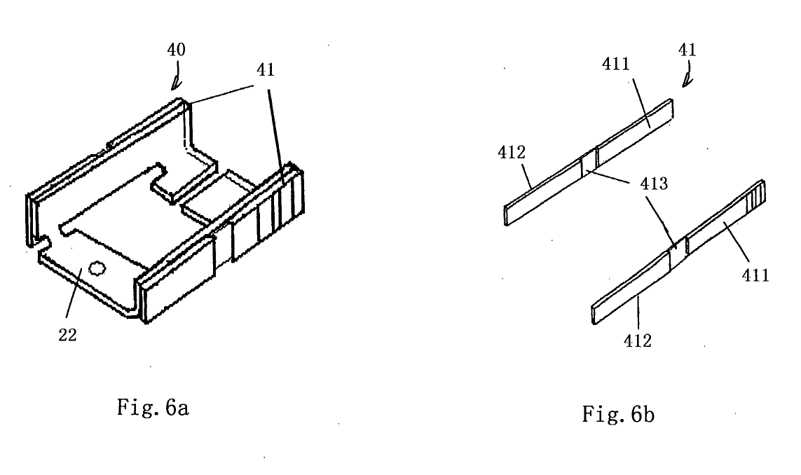

FIG. 6a to FIG. 6b show the structural views of the micro-actuator and its thin film PZT according to the third embodiment of this invention, which implements above-described principle.

FIG. 6a show the structural view of the assembled micro-actuator 40 of the third embodiment that comprises the metal frame 22 and thin-film PZT strips 41. More specifically, FIG. 6b shows two strips of thin film PZT 41 each constituted by the first thin film PZT piece 411 and the second thin film PZT piece 412 which are also coupled together by a substrate 413 in such manner that the first and second PZT pieces 411 and 412 are arranged on the substrate 413 in longitudinal direction (in series). As can be seen, the structural layout of the thin film PZT 41 of the third embodiment is similar to that of first embodiment. The third embodiment is different from the first embodiment in that the two strips of thin film PZT pieces 41 will be directly attached to the exterior side surface of each arm of the metal frame 22 without bending. Also electrical traces (not shown) may be formed on the substrate 413 for coupling the two pieces of thin film PZT 411 and 412 electrically.

The metal frame 22 of this third embodiment of the micro-actuator 40 is identical to that of the first and second embodiments, thus the further description to the metal frame is omitted. Similarly, another kind of metal frame 22′ can also be employed in the third embodiment.

In FIG. 6a, only the case that the two strips of the thin film PZT 41 are attached to the exterior side surface of the two arms of the metal frame 22 respectively is illustrated. However, it can be appreciated that the two strips of the thin film PZT 41 may be attached to the inner side surface of the two arms of the metal frame 22 respectively. Furthermore, it also feasible that one strips of the thin film PZT 41 is attached to the inner side surface of one arm while another strip is attached to the exterior side surface of the other arm, provided that the superposition effect will occur.

Even though each piece of thin film PZT 411, 412 of this embodiment can not use the length of 1 mm according to FIG. 5 due to the total length limitation of the micro-actuator side arm. But each piece of the thin film PZT 411, 412 can be designed to take an optimum length so that each piece PZT can produce maximum displacement. Since the thin film PZT 411 and 412 are fixedly attached to the arm of the metal frame 22, the displacement of each arm is a superposition of that of these two thin film PZT 411 and 412. An increased displacement of the micro-actuator 40 can also be achieved according to the arrangement of the third embodiment.

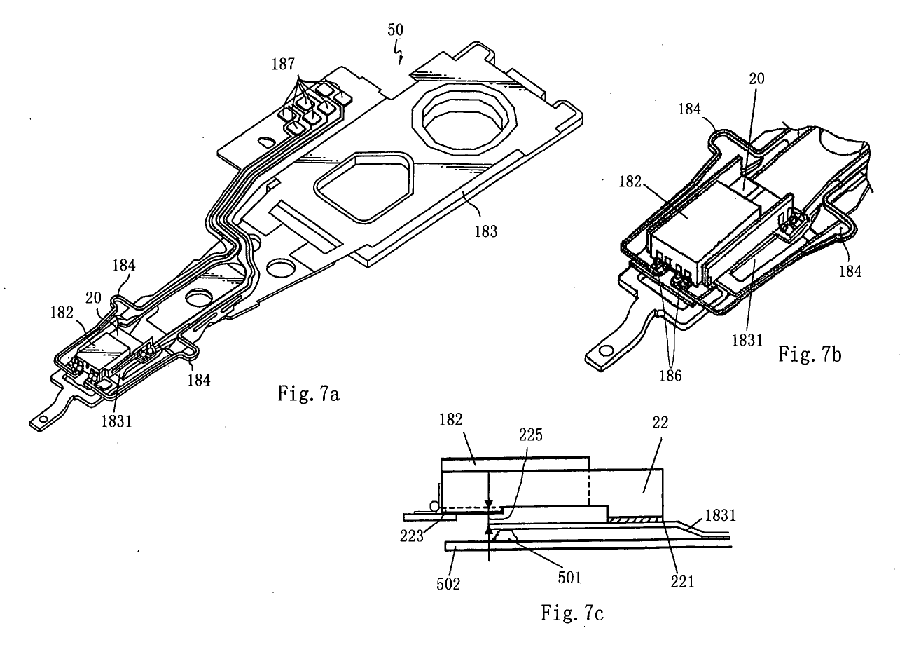

FIG. 7a shows a whole structure of an HGA 50 equipped with the micro-actuator 20 (or 30, 40) according to this invention. The HGA is equipped with a micro-actuator 20 for precise positioning of a magnetic/optical head element (not shown) at a suspension tongue 1831 of a suspension 183. FIG. 7b is an enlarged view of the front portion of the suspension 183.

As shown in FIG. 7a and FIG. 7b, the assembly of a slider 182 with at least one head element (not shown) and a micro-actuator 20 is disposed on a suspension tongue 1831 of the suspension of 183 by fixing the base piece of the metal frame of the micro-actuator 20 to the suspension tongue 1831 of the suspension 183. The slider 182 is mounted between the two arms of micro-actuator 20 and is capable of displacing in response to drive signal(s) applied to the thin film PZT. Slider 182 is electrically coupled to the suspension pads 187 by gold ball bonding (GBB) or solder bump bonding (SBB) 186 and suspension traces 184. Also, the thin film PZT is electrically coupled to the suspension pads 187 via suspension traces 184. The detailed description of the electricity connections that are known in the art will be omitted here. Although in the above mentioned embodiment all the pieces of the thin film PZT on each arm of the metal frame are all applied with a drive signal, it is possible that only two pieces of thin film PZT on one arm of the metal frame are applied with a drive signal only if the displacement of the arms caused by the thin film PZT can meet relevant requirements.

FIG. 7c is a side view of the micro-actuator 20 located on the suspension tongue 1831 of the suspension 183. The metal frame 22 supports the slider 182 by the support 223, and the base piece 221 is mounted on the suspension tongue 1831 partially via an insulation layer made of for example polymer. A protrusion 501 in the suspension load beam 502 supports the suspension tongue 1831. The gap 225 of about 30˜50 μm between the suspension tongue 1831 and the bottom surface of the support 223 of metal frame 22 will ensure the slider 182 to move smoothly when a voltage is applied to the thin film PZT, as mentioned above.

The HGA according to the present invention is not limited to the aforementioned structure. Furthermore, although it is not shown, a head drive IC chip may be mounted on the middle of the suspension 183.

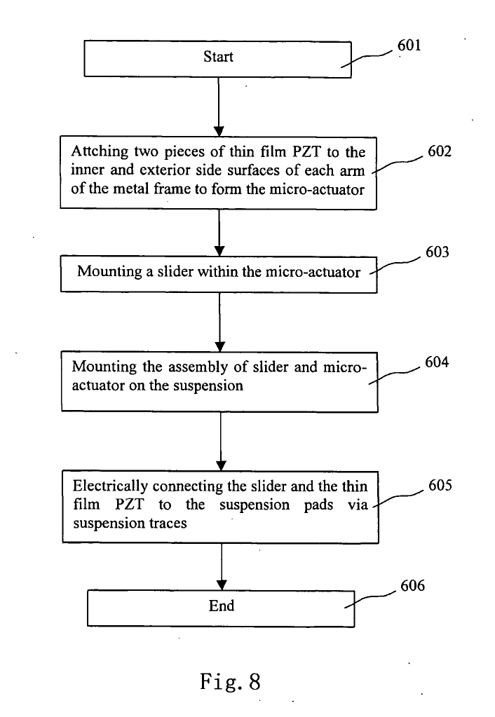

FIG. 8 is a flow chart showing the processes of manufacturing the HGA according to this invention.

The procedure starts at step 601. In step 602, two pieces of thin film PZT are attached to the inner and exterior side surfaces of each arm of the metal frame so as to form the micro-actuator as described in first or second embodiment, then the procedure proceeds to step 603, in which a slider with head element is mounted on the micro-actuator. In the next step 604, the assembly of the slider and the micro-actuator is mounted on a suspension tongue of a suspension of the head gimbal assembly by fixing the base piece of the micro-actuator thereto. In steps 605, the micro-actuator is connected to the suspension pad electrically, and the slider is connected to the suspension pad electrically via suspension traces. The procedure terminates in step 606 thus a HGA of this invention is manufactured.

Furthermore, the performance of the slider and the thin film PZT after being mounted may be tested after the HGA is manufactured.

Alternatively, the HGA of this invention may be manufactured in another procedure, in which the metal frame of the micro-actuator is firstly attached to the suspension prior to the attaching of the PZT thin film to the arm of the metal frame and mounting the slider to the micro-actuator.

Furthermore, in the shown manufacture process, the step of attaching the thin film PZT to the side surfaces of two arms of the metal frame may comprises following further steps: providing two strips of thin film PZT, each strip of the thin film PZT is constituted by two pieces of thin film PZT coupled by a substrate mechanically and electrically; bending each strip of thin film PZT at the middle portion of the substrate such that two pieces of thin film PZT constituting each strip of thin film PZT are substantially parallel to each other, attaching the folded two pieces of thin film PZT to the exterior and inner surface of one of the arms respectively in a manner that said arm is sandwiched between said two pieces of the thin film PZT.

On the other hand, another manufacture process for forming the HGA equipped with the micro-actuator 40 of the third embodiment is as following: attaching two pieces of thin film PZT in series to same side surface of each arms of a metal frame to form a micro-actuator of the third embodiment; mounting a slider with a head element within the micro-actuator; mounting the micro-actuator on a suspension by fixing a base piece of the metal frame onto a suspension tongue of the suspension; connecting the micro-actuator with the suspension and the head slider with the suspension electrically. This procedure is similar to that shown in FIG. 8 therefore it is not illustrated in a new flow chart. Similarly, in this process, the metal frame of the micro-actuator may also be firstly attached to the suspension prior to the attaching of the PZT thin film to the arm of the metal frame and mounting the slider to the micro-actuator.

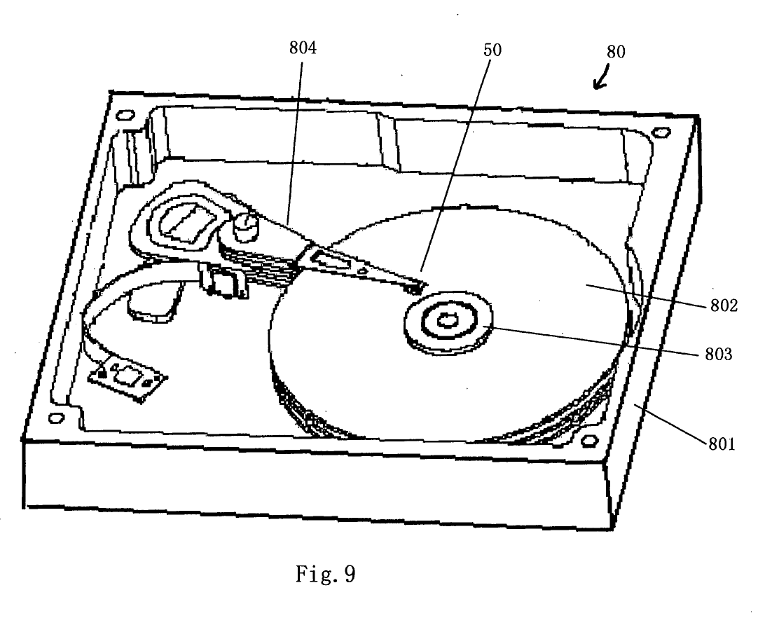

FIG. 9 shows a HDD 80 using the thin film PZT micro-actuator 20, 30 or 40 of this invention. It comprises a housing 801, a disk 802 accommodated in said housing 801; a pivot center 803, about which said disk rotates in said housing; a VCM 804 for driving the HGA 50 coupled to said VCM 804 to move above the surface of the disk 802. Said head gimbal assembly 50 comprises a micro-actuator 20, 30 or 40 of this invention.

Although in the aforementioned embodiments, the micro-actuator is used in HGA of disk drive unit, it can also be used in other devices which are required to adjusting displacement of an object to be fixed to, as is obvious to those skilled in the art. Many widely different embodiments of the present invention may be constructed without departing from the spirit and scope of the present invention. For example, more than two pieces of thin film PZT may be attached to the side surface(s) of each arm of the metal frame in any other manners, such as by combining the first and third embodiments, i.e., both the inner and exterior side surface of each arm are provided with more than one piece of thin film PZT, to obtain larger displacement, provided that a superposition effect occurs. It should be understood that the present invention is not limited to the specific embodiments described in the specification, except as defined in the appended claims.

What is claimed is:

1. A micro-actuator comprising a metal frame which includes a base piece and two opposite arms extending from the base piece, characterized in that at least two pieces of thin film PZT are attached to the side surface(s) of each one of said two opposite arms respectively in such a manner that the displacement of each arm is increased due to superposition effect when each arm displaces together with the thin film PZT attached thereon in response to drive signal(s) applied to the thin film PZT.

2. A micro-actuator as claimed in claim 1, wherein said at least two pieces of thin film PZT are attached to the exterior and inner side surfaces of each said arm respectively.

3. A micro-actuator as claimed in claim 2, wherein the said at-least two pieces of thin film PZT attached to the exterior and inner side surfaces of each arm are coupled together mechanically and electrically by a substrate.

4. A micro-actuator as claimed in claim 3, wherein said at least two pieces of thin film PZT are coupled by the substrate in such a manner that the substrate crosses over the front or rear end of the arm.

5. A micro-actuator as claimed in claim 3, wherein said at least two pieces of thin film PZT are coupled by the substrate in such a manner that the substrate crosses over the top edge of the arm.

6. A micro-actuator as claimed in claim 1, wherein said at least two pieces of thin film PZT are attached to the same side surface of each said arm in series.

7. A micro-actuator as claimed in claim 6, wherein said at least two pieces of thin film PZT attached to the same side surface of each arm are coupled together mechanically and electrically by a substrate.

8. A micro-actuator as claimed in claim 3, wherein said substrate is of soft polymer, on which electrical traces are formed for electrically coupling said two pieces of thin film PZT.

9. A micro-actuator as claimed in claim 7, wherein said substrate is of soft polymer, on which electrical traces are formed for electrically coupling said two pieces of thin film PZT.

10. A head gimbal assembly comprising:
a micro-actuator, which comprises a metal frame which includes a base piece and two opposite arms extending from the base piece, wherein at least two pieces of thin film PZT are attached to the side surface(s) of each one of said two opposite arms respectively in such a manner that the displacement of each arm is increased due to superposition effect when each arm displaces together with the thin film PZT attached thereon in response to drive signal(s) applied to the thin film PZT;
a slider with at least one head element, said slider being accommodated in said metal frame of the micro-actuator so that said slider can be actuated by said micro-actuator;
a suspension, said micro-actuator being located on the suspension tongue of said suspension by fixing the base piece thereto such that said two arms together with the slider can move independently of the suspension.

11. An information recording disk unit comprising
a disk;
a pivot center, about which said disk rotates,
a VCM for driving a head element to move above the surface of the disk, and
a head gimbal assembly connected to said VCM for head displacement adjustment,
characterized in that said head gimbal assembly comprises a micro-actuator, said micro-actuator comprises a metal frame which includes a base piece and two opposite arms extending from the base piece, wherein at least two pieces of thin film PZT are attached to the side surface(s) of each one of said two opposite arms respectively in such a manner that the displacement of each arm is increased due to superposition effect when each arm displaces together with the thin film PZT attached thereon in response to drive signal(s) applied to the thin film PZT.

12. A method of manufacturing a head gimbal assembly, comprising the steps of:
attaching two pieces of thin film PZT to the inner and exterior side surfaces of each arms of a metal frame respectively to form a micro-actuator;
mounting a slider with a head element within the micro-actuator;
mounting the micro-actuator on a suspension by fixing a base piece of the metal frame onto a suspension tongue of the suspension;
connecting the micro-actuator with the suspension and the head slider with the suspension electrically.

13. The method of manufacturing a head gimbal assembly as claimed in claim 12, wherein said step of attaching thin film PZT to the side surface of each arm further comprises following steps:
providing two strips of thin film PZT, each strip of the thin film PZT is constituted by two pieces of thin film PZT coupled by a substrate mechanically and electrically,
bending each strip of thin film PZT at the middle portion of the soft substrate such that two pieces of thin film PZT constituting each strip of thin film PZT are substantially parallel to each other,
attaching the folded two pieces of thin film PZT to the exterior and inner surface of each of the arms respectively in a manner that said each of the arms are sandwiched by the folded two pieces of the thin film PZT and said soft substrate crosses over the arm.

14. A method of manufacturing a head gimbal assembly, comprising the steps of:
attaching two pieces of thin film PZT to same side surface of each arms of a metal frame in series to form a micro-actuator;
mounting a slider with a head element within the micro-actuator;
mounting the micro-actuator on a suspension by fixing a base piece of the metal frame onto a suspension tongue of the suspension;
connecting the micro-actuator with the suspension and the head slider with the suspension electrically.
